(19) United States
(12) Patent Application Publication
(10) Pub. No.: US 2022/0239070 A1
(43) Pub. Date: Jul. 28, 2022

(54) VERTICAL-CAVITY SURFACE-EMITTING LASER

(71) Applicant: SUMITOMO ELECTRIC INDUSTRIES, LTD., Osaka (JP)

(72) Inventor: Daisuke INOUE, Osaka-shi (JP)

(73) Assignee: SUMITOMO ELECTRIC INDUSTRIES, LTD., Osaka (JP)

(21) Appl. No.: 17/569,719

(22) Filed: Jan. 6, 2022

(30) Foreign Application Priority Data
Jan. 25, 2021 (JP) 2021-009633

(51) Int. Cl. H01S 5/22; H01S 5/042; H01S 5/183

(52) U.S. Cl. CPC H01S 5/2213; H01S 5/18361; H01S 5/0425

(57) ABSTRACT

A vertical cavity surface emitting laser includes a substrate that has a main surface including a first area and a second area, a post that is provided on or above the first area, and that includes a first-conductive first distributed Bragg reflector provided on or above the first area, an active layer provided on the first distributed Bragg reflector, and a second-conductive second distributed Bragg reflector provided on the active layer, a stack that is provided on or above the main surface, and that includes an upper surface having at least one recess portion disposed above the second area, a resin portion that is disposed in the at least one recess portion, and an electrode pad that is provided on the resin portion and that is electrically connected to either one of the first distributed Bragg reflector and the second distributed Bragg reflector.

### CROSS REFERENCE TO RELATED APPLICATIONS

This application claims priority based on Japanese Patent Application No. 2021-009633 filed on Jan. 25, 2021, and the entire contents of the Japanese patent application are incorporated herein by reference.

### TECHNICAL FIELD

The present disclosure relates to a vertical-cavity surface-emitting laser.

### BACKGROUND

Non-patent document 1 (A. N. Al-Omari and K. L. Lear, “VCSELs with a self-aligned contact and copper-plated heatsink,” in IEEE Photonics Technology Letters, vol. 17, no. 9, pp. 1767-1769, Sept. 2005, doi:10.1109/LPT.2005.851938.) discloses vertical-cavity surface-emitting lasers with a polyimide section placed under an electrode pad to reduce the capacitance caused by the electrode pad.

### SUMMARY

The present disclosure provides a vertical-cavity surface-emitting laser including a substrate that has a main surface including a first area and a second area, a post that is provided on or above the first area, and that includes a first-conductive first distributed Bragg reflector provided on or above the first area, an active layer provided on the first distributed Bragg reflector, and a second-conductive second distributed Bragg reflector provided on the active layer, a stack that is provided on or above the main surface, and that includes an upper surface having at least one recess portion disposed above the second area, a resin portion that is disposed in the at least one recess portion, and an electrode pad that is provided on the resin portion and that is electrically connected to either one of the first distributed Bragg reflector and the second distributed Bragg reflector.

### BRIEF DESCRIPTION OF THE DRAWINGS

The foregoing and other purposes, aspects and advantages will be better understood from the following detailed description with reference to the drawings.

FIG. 1 shows a schematic plan view of a vertical-cavity surface-emitting laser according to one embodiment.

FIG. 2 shows a cross-sectional view along line II-II of FIG. 1.

FIG. 3 shows a cross-sectional view along line III-III of FIG. 1.

FIG. 4 shows a schematic plan view of a portion of a vertical-cavity surface-emitting laser according to one embodiment.

FIG. 5 shows a cross-sectional view of FIG. 2 with a portion enlarged.

FIG. 6 shows a schematic cross-sectional view in a step of a method for manufacturing a vertical-cavity surface-emitting laser according to one embodiment.

FIG. 7 shows a schematic cross-sectional view in a step of a method for manufacturing a vertical-cavity surface-emitting laser according to one embodiment.

FIG. 8 shows a schematic cross-sectional view in a step of a method for manufacturing a vertical-cavity surface-emitting laser according to one embodiment.

FIG. 9 shows a schematic cross-sectional view in a step of a method for manufacturing a vertical-cavity surface-emitting laser according to one embodiment.

FIG. 10 shows a schematic view of a part of a vertical-cavity surface-emitting laser according to another embodiment.

FIG. 11 shows a schematic plan view of a part of a vertical-cavity surface-emitting laser in a first experimental example.

FIG. 12 is a schematic plan view of a part of a vertical-cavity surface-emitting laser in a second experimental example.

FIG. 13 is a schematic plan view of a part of a vertical-cavity surface-emitting laser in a third experimental example.

FIG. 14 shows a schematic plan view of a part of a vertical-cavity surface-emitting laser in a fourth experimental example.

FIG. 15 shows a schematic plan view of a part of a vertical-cavity surface-emitting laser in a fifth experimental example.

FIG. 16 shows a graph of capacitances caused by electrode pads in vertical-cavity surface-emitting lasers of the first to fifth experimental examples.

### DETAILED DESCRIPTION

The above polyimide section in Non-patent document 1 is formed by removing a polyimide layer formed on an upper surface of a semiconductor stack, except for the portion placed under the electrode pad. Therefore, the polyimide section has a mesa shape that protrudes from the upper surface of the semiconductor stack.

The present disclosure provides a vertical-cavity surface-emitting laser that can prevent a resin portion from protruding from the upper surface of the stack, or that can reduce the amount of a protrusion of the resin portion protruding from the upper surface of the stack.

### Description of Embodiments of the Present Disclosure

A vertical-cavity surface-emitting laser according to an aspect of the present disclosure includes a substrate that has a main surface including a first area and a second area, a post that is provided on or above the first area, and that includes a first-conductive first distributed Bragg reflector provided on or above the first area, an active layer provided on the first distributed Bragg reflector, and a second-conductive second distributed Bragg reflector provided on the active layer, a stack that is provided on or above the main surface, and that includes an upper surface having at least one recess portion disposed above the second area, a resin portion that is disposed in the at least one recess portion, and an electrode pad that is provided on the resin portion and that is electrically connected to either one of the first distributed Bragg reflector and the second distributed Bragg reflector.

According to the above vertical-cavity surface-emitting laser, the resin portion is disposed in the at least one recess portion. Therefore, the resin portion can be prevented from protruding from the upper surface of the stack, or the amount of a protrusion of the resin portion protruding from the upper surface of the stack can be reduced.

The at least one recess portion may include a plurality of recess portions. In this case, a volume of the resin portion disposed in each of the recess portions can be reduced. Therefore, a stress between the resin portion and the stack caused by a shrinkage of the resin portion can be reduced.

The vertical-cavity surface-emitting laser may further include a partition wall that separates adjacent recess portion of the plurality of recess portions from each other. The partition wall may have an annular shape when seen from a direction orthogonal to the main surface of the substrate. In this case, the concentration of the stress at a specific point between the partition wall and the resin portion can be suppressed.

The vertical-cavity surface-emitting laser may further include a partition wall that separates adjacent recess portion of the plurality of recess portions from each other. The partition wall may be connected to the stack. In this case, the partition wall is supported by the stack, which can prevent the partition wall from collapsing.

The partition wall may have an upper surface having a width of 1 μm or greater. In this case, the partition wall can be made thicker, which makes it more difficult for the partition wall to collapse.

The partition wall may have a side surface inclined with respect to the main surface of the substrate. An angle from the main surface to the side surface through an inner portion of the partition wall may be less than 90°. In this case, the stress between the side surface of the partition wall and the resin portion can be reduced.

The vertical-cavity surface-emitting laser may further include a contact layer that is provided above the main surface. The contact layer may extend from the first area to the second area. The contact layer may be connected to the first distributed Bragg reflector. The electrode pad may be electrically connected to the second distributed Bragg reflector. In this case, the capacitance between the electrode pad and the contact layer can be reduced.

Hereinafter, embodiments of the present disclosure will be described in detail with reference to the drawings. In the description of the drawings, like or corresponding elements are denoted by like reference numerals and redundant descriptions thereof will be omitted.

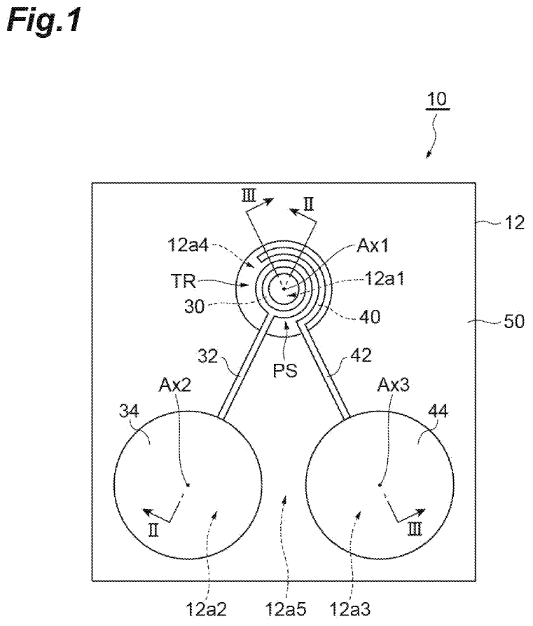

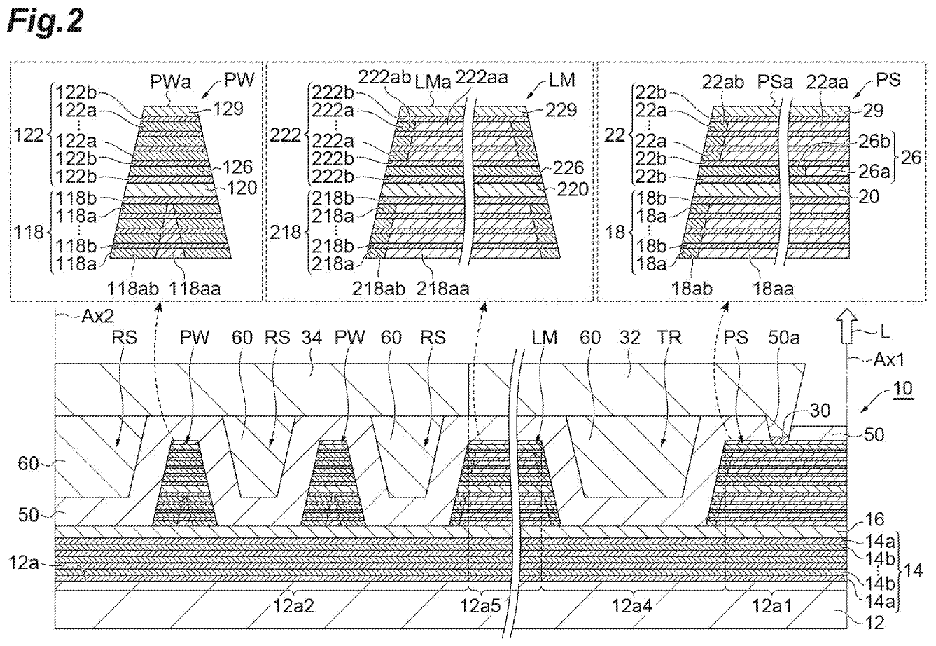

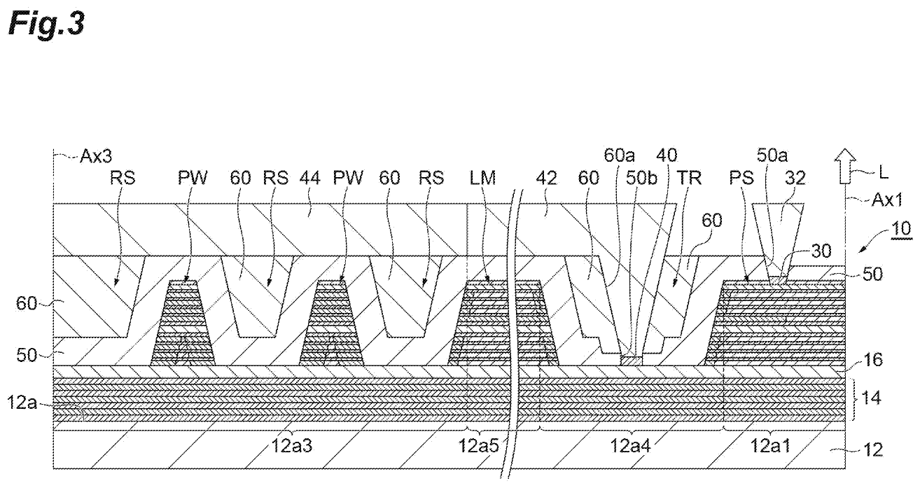

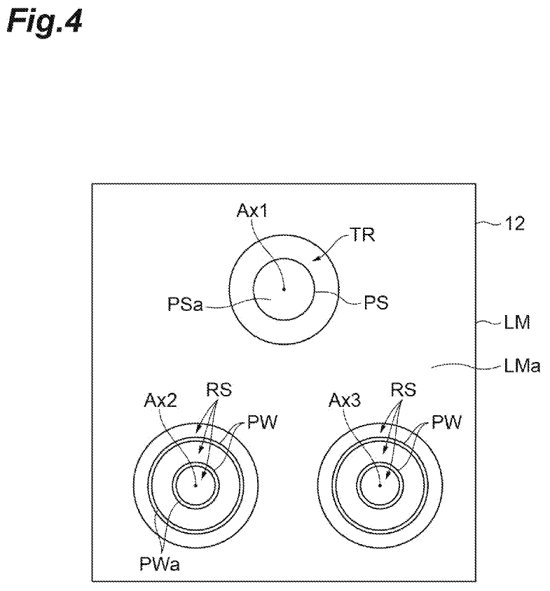

FIG. 1 shows a schematic plan view of a vertical-cavity surface-emitting laser according to one embodiment. FIG. 2 shows a cross-sectional view along line II-II of FIG. 1. FIG. 3 shows a cross-sectional view along line III-III of FIG. 1. FIG. 4 shows a schematic plan view of a portion of a vertical-cavity surface-emitting laser according to one embodiment. A vertical-cavity surface-emitting laser (VCSEL) 10 shown in FIGS. 1 to 4 is, for example, a laser for communication. Vertical-cavity surface-emitting laser 10 emits a laser light L along an axis Ax1. A wavelength of the laser light L is 840 nm or more and 860 nm or less, for example. Vertical-cavity surface-emitting laser 10 has a substrate 12, a post PS, a stack LM, and a resin portion 60.

Substrate 12 may be a semi-insulating substrate. Substrate 12 has a main surface 12a that intersects (e.g., orthogonally) axis Ax1. Main surface 12a includes a first area 12a1 and a second area 12a2. Axis Ax1 passes through first area 12a1. First area 12a1 has a circle centered on axis Ax1, for example. Second area 12a2 may be away from first area 12a1. An axis Ax2 which is parallel to axis Ax1 passes through second area 12a2. Second area 12a2 has a circle centered on axis Ax2, for example. Main surface 12a may have a third area 12a3 away from first area 12a1 and second area 12a2. An axis Ax3 parallel to axis Ax1 passes through third area 12a3. Third area 12a3 has a circle centered on axis Ax3, for example. Main surface 12a may have a fourth area 12a4 surrounding first area 12a1. Fourth area 12a4 has an annular shape centered on axis Ax1, for example. Main surface 12a may have a fifth area 12a5 surrounding first area 12a1 through fourth area 12a4. Fifth area 12a5 is the area of main surface 12a excluding first area 12a1 to fourth area 12a4. The neighboring areas share a boundary with each other. A carrier concentration of substrate 12 is, for example, 1×10¹⁵ cm⁻³ or less. Substrate 12 may be a III-V compound semiconductor substrate, such as a GaAs substrate.

An undoped DBR (distributed Bragg reflector) portion 14 may be provided on main surface 12a of substrate 12. Distributed Bragg reflector portion 14 is provided on the entire main surface 12a. Distributed Bragg reflector portion 14 has semiconductor layers 14a and semiconductor layers 14b arranged alternately along axis Ax1. Semiconductor layer 14a has a refractive index lower than a refractive index of semiconductor layer 14b. Each of semiconductor layers 14a and semiconductor layers 14b contains a III-V compound semiconductor, such as AlGaAs.

Above main surface 12a of substrate 12, a contact layer 16 may be provided. Contact layer 16 is provided on distributed Bragg reflector portion 14. Distributed Bragg reflector portion 14 (third distributed Bragg reflector) may be disposed between substrate 12 and contact layer 16. Contact layer 16 is a first-conductive (e.g., n-type) semiconductor layer. Contact layer 16 includes a III-V compound semiconductor, such as AlGaAs. Examples of n-type dopants include silicon. Contact layer 16 extends from first area 12a1 to second area 12a2. Contact layer 16 may be provided above the entire main surface 12a.

Post PS is provided above first area 12a1. A lower surface of post PS may be connected to contact layer 16. An upper surface PSa of post PS has a circular shape centered on axis Ax1, for example. When seen from axis Ax1, upper surface PSa of post PS may overlap with first area 12a1. Post PS may have a side surface that is inclined with respect to main surface 12a of substrate 12.

Post PS includes a first-conductive distributed Bragg reflector portion 18 (first distributed Bragg reflector) above first area 12a1, an active layer 20 on distributed Bragg reflector portion 18, and a second-conductive (e.g. p-type) distributed Bragg reflector portion 22 (second distributed Bragg reflector) on active layer 20. The second-conductive type is the opposite conductivity type to the first-conductive type.

Distributed Bragg reflector portion 18 is connected to contact layer 16. Distributed Bragg reflector portion 18 has first layers 18a and second layers 18b arranged alternately along axis Ax1. Each first layer 18a has a semiconductor layer 18aa and an oxide layer 18ab surrounding semiconductor layer 18aa. Each second layer 18b is a semiconductor layer. Semiconductor layer 18aa has a refractive index lower than a refractive index of second layer 18b. Each of semiconductor layers 18aa and second layers 18b contains a III-V compound semiconductor, such as AlGaAs.

Active layer 20 has, for example, a multiple-quantum well structure. The multiple-quantum well structure may include GaAs layers (or AlGaAs layers) and AlGaAs layers alternately aligned along axis Ax1.

Distributed Bragg reflector portion 22 has third layers 22a and fourth layers 22b arranged alternately along axis Ax1. Each third layer 22a has a semiconductor layer 22aa and an oxide layer 22ab surrounding semiconductor layer 22aa. Each fourth layer 22b is a semiconductor layer. Semiconductor layer 22aa has a refractive index lower than a refractive index of fourth layer 22b. Each of semiconductor layers 22aa and fourth layers 22b contains a III-V compound semiconductor, such as AlGaAs.

Distributed Bragg reflector portion 22 may include a current confinement structure 26. Current confinement structure 26 has a current aperture portion 26a and an insulator portion 26b. Insulator portion 26b surrounds current aperture portion 26a. Current aperture portion 26a includes a III-V compound semiconductor, such as AlGaAs. Axis Ax1 passes through current aperture portion 26a. Current aperture portion 26a is cylindrical, for example. Insulator portion 26b contains an oxide, for example, aluminum oxide.

Post PS may include a contact layer 29 provided on distributed Bragg reflector portion 22. An upper surface of contact layer 29 may be upper surface PSa of post PS. Contact layer 29 is a second-conductive semiconductor layer. Contact layer 29 may include a III-V compound semiconductor, such as AlGaAs.

Stack LM is provided above main surface 12a. Stack LM is provided above second area 12a2 to fifth area 12a5. A lower surface of stack LM may be connected to contact layer 16. An upper surface LMa of stack LM may be flush with upper surface PSa of post PS. Stack LM may have a side surface that is inclined with respect to main surface 12a of substrate 12.

Upper surface LMa has at least one recess portion RS disposed over each of second area 12a2 and third area 12a3. In this embodiment, a plurality of recess portions RS is disposed on each of second area 12a2 and third area 12a3. A bottom of each recess portion RS reaches the upper surface of contact layer 16. Upper surface LMa may have a trench TR located above fourth area 12a4. Trench TR is provided to surround post PS. A bottom of trench TR reaches the upper surface of contact layer 16.

Stack LM has the same layer structure as post PS. Stack LM includes a lower stack 218 on contact layer 16, an intermediate layer 220 on lower stack 218, and an upper stack 222 on intermediate layer 220.

Lower stack 218 has fifth layers 218a and sixth layers 218b arranged alternately along axis Ax2 or axis Ax3. Each fifth layer 218a has a semiconductor layer 218aa and an oxide layer 218ab surrounding semiconductor layer 218aa. Each sixth layer 218b is a semiconductor layer. Semiconductor layer 218aa and sixth layer 218b have the same configurations as semiconductor layer 18aa and second layer 18b, respectively. Intermediate layer 220 has the same configuration as active layer 20. Upper stack 222 has seventh layers 222a and eighth layers 222b arranged alternately along axis Ax2 or axis Ax3. Each seventh layer 222a has a semiconductor layer 222aa and an oxide layer 222ab surrounding semiconductor layer 222aa. Each eighth layer 222b is a semiconductor layer. Semiconductor layer 222aa and eighth layer 222b have the same configurations as semiconductor layer 22aa and fourth layer 22b, respectively. Upper stack 222 may include a layer 226, which has the same configuration as current confinement structure 26.

Resin portion 60 is disposed in each of recess portions RS and in trench TR. Resin portion 60 may fill each of recess portions RS and trench TR. Resin portion 60 includes a resin with a low dielectric constant. Examples of resins include benzocyclobutene (BCB) or polyimide. Resin portion 60 does not have to be placed in trench TR.

Adjacent recess portions RS may be separated from each other by a partition wall PW. Partition wall PW is provided above second area 12a2 and third area 12a3. A lower surface of partition wall PW may be connected to contact layer 16. An upper surface PWa of partition wall PW may be flush with upper surface PSa of post PS. In this embodiment, as shown in FIG. 4, a plurality of partition walls PW is concentrically arranged with axis Ax2 or axis Ax3 as the center. In other words, each partition wall PW has an annular shape centered on axis Ax2 or axis Ax3 when viewed from the direction of axis Ax2 or axis Ax3. In FIG. 4, the structures on post PS, stack LM, partition wall PW, recess portion RS, and trench TR are omitted.

Each partition wall PW has the same layer structure as stack LM. Partition wall PW includes a lower stack 118 on contact layer 16, an intermediate layer 120 on lower stack 118, and an upper stack 122 on intermediate layer 120.

Lower stack 118 has ninth layers 118a and tenth layers 118b arranged alternately along axis Ax2 or axis Ax3. Each ninth layer 118a has a semiconductor layer 118aa and an oxide layer 118ab surrounding semiconductor layer 118aa. Each tenth layer 118b is a semiconductor layer. Semiconductor layer 118aa and tenth layer 118b have the same configurations as semiconductor layer 18aa and second layer 18b, respectively. Intermediate layer 120 has the same structure as active layer 20. Upper stack 122 has eleventh layers 122a and twelfth layers 122b arranged alternately along axis Ax2 or axis Ax3. In this embodiment, each eleventh layer 122a is an oxide layer. Each twelfth layer 122b has the same configuration as fourth layer 22b. Upper stack 122 may include a layer 126. In this embodiment, layer 126 has the same configuration as insulator portion 26b of current confinement structure 26.

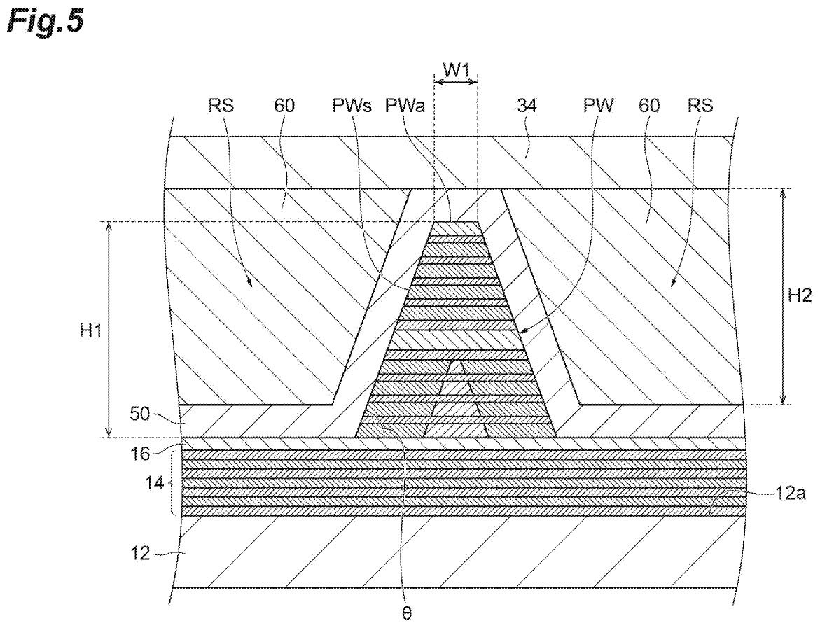

FIG. 5 shows a cross-sectional view of FIG. 2 with a portion enlarged. As shown in FIG. 5, partition wall PW may have a width W of 1 μm or more at upper surface PWa of partition wall PW. Partition wall PW may have a side surface PWs that is inclined with respect to main surface 12a of substrate 12. Side surface PWs is inclined so that the width of partition wall PW decreases gradually as it moves away from main surface 12a. An angle θ from main surface 12a to side surface PWs through an inner portion of partition wall PW may be less than 90°, equal to or less than 80°, or equal to or greater than 60°. Partition wall PW may have a height H1 of 5 μm or greater. The height H1 is a distance from the lower surface of partition wall PW to upper surface PWa. The height H1 may be the same as a thickness H2 of resin portion 60 or a depth of recess portion RS.

An insulating layer 50 may be provided on post PS, stack LM, partition wall PW, each recess portion RS and trench TR. Insulating layer 50 is disposed between each recess portion RS and resin portion 60, and between trench TR and resin portion 60. Insulating layer 50 has an opening 50a on upper surface PSa of post PS, as shown in FIG. 2 and FIG. 3. Through opening 50a, an electrode 30 is connected to upper surface PSa of post PS. Electrode 30 is provided to surround axis Ax1. Insulating layer 50 has an opening 50b at the bottom of trench TR, as shown in FIG. 3. Through opening 50b, an electrode 40 is connected to contact layer 16. Electrode 40 is disposed to surround post PS. A voltage is applied between electrode 30 and electrode 40 so that the laser light L is emitted from vertical-cavity surface-emitting laser 10. Insulating layer 50 may include a single layer or multiple layers. Insulating layer 50 may include, for example, a silicon nitride layer or a silicon oxynitride layer.

Vertical-cavity surface-emitting laser 10 has an electrode pad 34 and an electrode pad 44. Electrode pad 34 is connected to electrode 30 by a wiring 32. Electrode pad 34 is electrically connected to distributed Bragg reflector portion 22. Wiring 32 is located on insulating layer 50 and resin portion 60, and extends from first area 12a1 to second area 12a2. Electrode pad 34 is disposed over second area 12a2. Electrode pad 34 is provided on insulating layer 50 and resin portion 60. Electrode pad 34 extends along main surface 12a. Electrode pad 34 has a circular shape, for example, with axis Ax2 as the center when seen from axis Ax2. A diameter of electrode pad 34 is, for example, 40 μm or more. Electrode pad 34 includes, for example, a metal such as gold.

Electrode pad 44 is connected to electrode 40 by a wiring 42. Electrode pad 44 is electrically connected to distributed Bragg reflector portion 18. Wiring 42 is provided on insulating layer 50 and resin portion 60. Wiring 42 extends from first area 12a1 to third area 12a3 on insulating layer 50 and resin portion 60. Electrode pad 44 is provided over third area 12a3. Electrode pad 44 is provided on insulating layer 50 and resin portion 60. Electrode pad 44 extends along main surface 12a. Electrode pad 44 has a circular shape, for example, with axis Ax3 as the center when seen from axis Ax3. A diameter of electrode pad 44 is, for example, 40 μm or more. Electrode pad 44 includes a metal, such as gold, for example.

According to vertical-cavity surface-emitting laser 10, since resin portion 60 is placed within each of recess portions RS, it is possible to prevent resin portion 60 from protruding from upper surface LMa of stack LM, or to reduce the amount of a protrusion of resin portion 60 protruding from upper surface LMa of stack LM. Also, by adjusting the depth of recess portion RS, a thickness H2 of resin portion 60 can be accurately controlled. Furthermore, resin portion 60 can reduce the capacitance caused by electrode pad 34 or electrode pad 44. For example, the capacitance between electrode pad 34 and contact layer 16 can be reduced. For example, the capacitance between electrode pad 44 and contact layer 29 can be reduced. The modulation bandwidth of vertical-cavity surface-emitting laser 10 can be increased when the capacitance is reduced.

When stack LM includes a plurality of recess portions RS, the volume of resin portion 60 disposed in each recess portion RS can be reduced. Therefore, the stress generated between resin portion 60 and each recess portion RS caused by the shrinkage of resin portion 60 can be reduced. Therefore, resin portion 60 can be prevented from detaching from each recess portion RS.

When partition wall PW has an annular shape, it is possible to prevent stress from being concentrated at a specific point (e.g., corner) between partition wall PW and resin portion 60.

If partition wall PW has a width W of 1 μm or more, partition wall PW can be thickened, which makes it difficult for partition wall PW to collapse.

If the angle θ between main surface 12a of substrate 12 and side surface PWs of partition wall PW is less than 90°, the stress between side surface PWs of partition wall PW and resin portion 60 can be reduced.

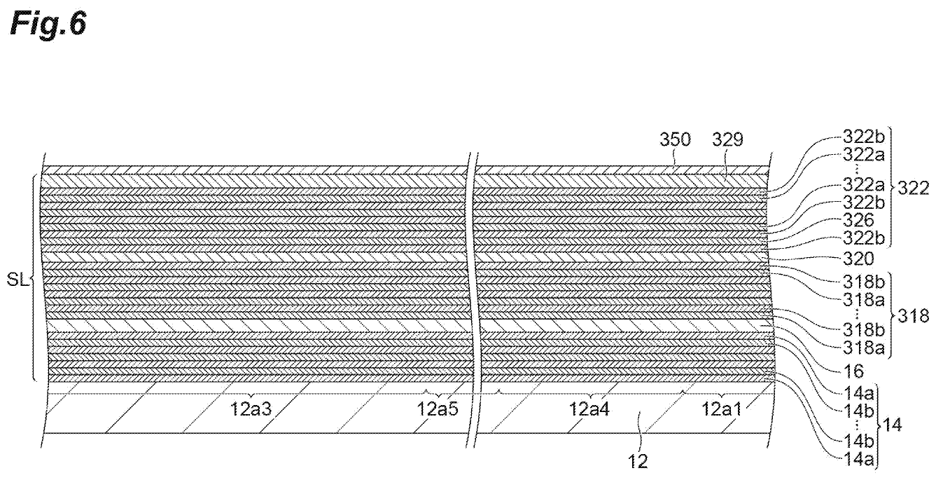

Each of FIGS. 6 to 9 shows a schematic cross-sectional view in a step of a method for manufacturing a vertical-cavity surface-emitting laser according to an embodiment. Vertical-cavity surface-emitting laser 10 described above may be fabricated as follows.

(Formation of Stack)

First, as shown in FIG. 6, a semiconductor stack SL and an insulating layer 350 are formed on main surface 12a of substrate 12. Specifically, distributed Bragg reflector portion 14, contact layer 16, a semiconductor stack 318 to be distributed Bragg reflector portion 18, a semiconductor layer 320 to be active layer 20, a semiconductor stack 322 to be distributed Bragg reflector portion 22, a semiconductor layer 329 to be contact layer 29, and insulating layer 350 are formed on main surface 21a in order. Semiconductor stack 318 includes semiconductor layers 318a and 318b, which are to be first layer 18a and second layer 18b, respectively. Semiconductor stack 322 includes a semiconductor layer 322a and a semiconductor layer 322b to be third layer 22a and fourth layer 22b, respectively, and includes a semiconductor layer 326 to be current confinement structure 26. Each layer constituting semiconductor stack SL is formed by, for example, organometallic vapor phase epitaxy or molecular beam epitaxy.

After the formation of insulating layer 350, protons may be injected into portions of semiconductor stack 322 above second area 12a2 to fifth area 12a5.

(Formation of Trench)

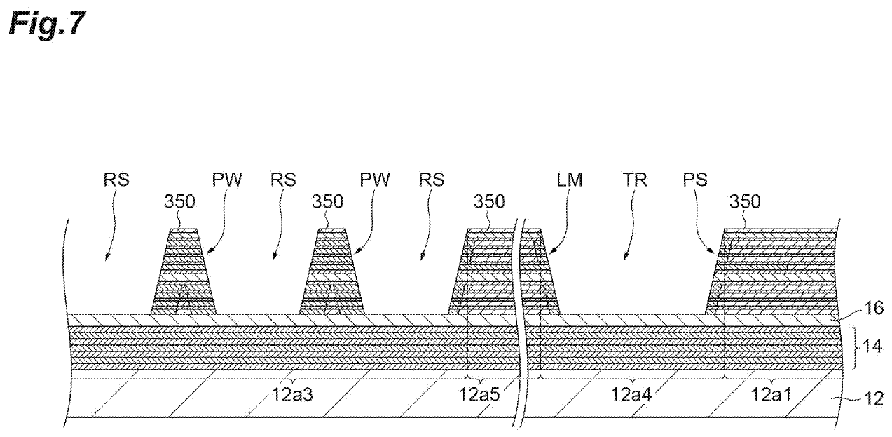

Next, as shown in FIG. 7, trench TR is formed above fourth area 12a4. In addition, recess portions RS are formed above second area 12a2 and third area 12a3. As a result, post PS surrounded by trench TR, partition walls PW between adjacent recess portions RS, and stack LM between trench TR and recess portion RS are formed. Trench TR and recess portions RS may be formed simultaneously, for example, by dry etching insulating layer 350, semiconductor layer 329, semiconductor stack 322, semiconductor layer 320, and semiconductor stack 318.

(Oxidation)

Next, as shown in FIG. 7, side surface of post PS is oxidized by exposing it to oxygen-containing gas such as water vapor. By the oxidation, current confinement structure 26 is formed. Side surfaces of stack LM and partition wall PW may be oxidized at the same time.

(Formation of Insulating Layer)

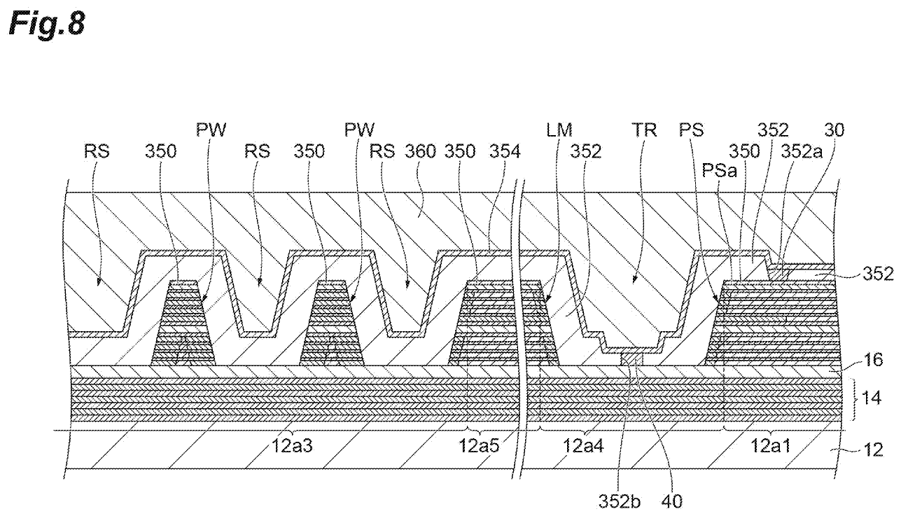

Next, as shown in FIG. 8, an insulating layer 352 is formed on post PS, stack LM, partition walls PW, each recess portion RS and trench TR. In insulating layer 352, an opening 352a is formed on upper surface PSa of post PS, and an opening 352b is formed on the bottom of trench TR.

(Formation of Electrode)

Next, as shown in FIG. 8, electrode 30 is formed in opening 352a and electrode 40 is formed in opening 352b. Then, an insulating layer 354 is formed on insulating layer 352, electrode 30 and electrode 40.

(Formation of Resin Layer)

Next, as shown in FIG. 8, a resin layer 360, which is to be resin portion 60, is formed on insulating layer 354. Resin layer 360 may be formed by applying a liquid resin material on insulating layer 354 and then curing the resin material.

(Formation of Resin Portion)

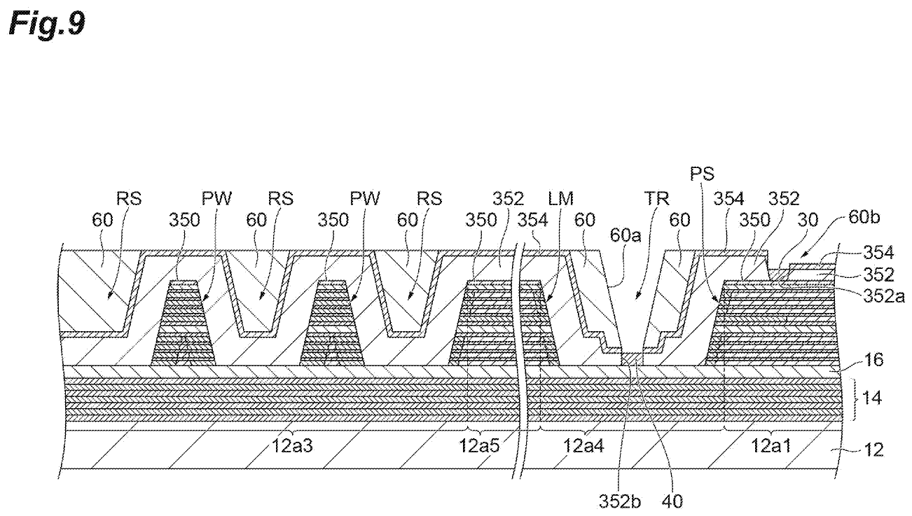

Next, as shown in FIG. 9, resin portion 60 is formed by etching resin layer 360. For example, first, the entire surface of resin layer 360 is etched to expose insulating layer 354. Then, by removing a part of resin layer 360 by photolithography and etching, an opening 60a is formed on electrode 40, and opening 50b is formed on electrode 30. Then, the portions of insulating layer 354 on electrode 30 and electrode 40 are removed by photolithography and etching. In this way, insulating layer 50 is formed from insulating layer 350, insulating layer 352, and insulating layer 354.

(Formation of Wiring and Electrode Pad)

Next, wiring 32, wiring 42, electrode pad 34, and electrode pad 44 shown in FIG. 3 are formed by the lift-off method.

(Cutting)

Next, substrate 12 is cut to separate the elements. The cutting is carried out, for example, by cleavage or dicing. Thus, a plurality of vertical-cavity surface-emitting lasers 10 is manufactured.

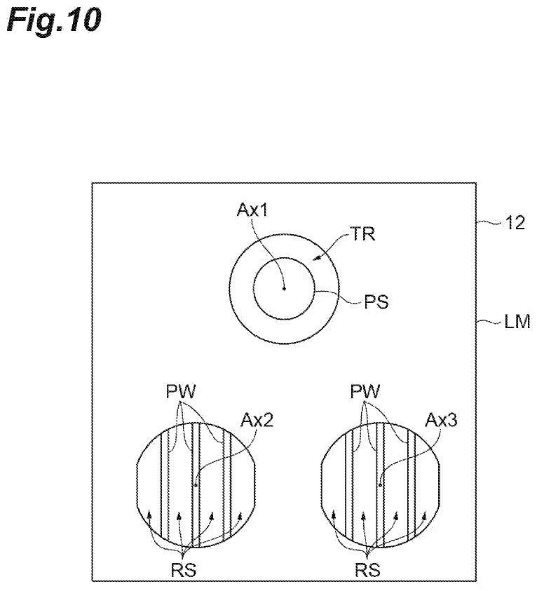

FIG. 10 shows a schematic view of a part of a vertical-cavity surface-emitting laser according to another embodiment. A vertical-cavity surface-emitting laser shown in FIG. 10 has the same configuration as vertical-cavity surface-emitting laser 10 except that the shape of partition wall PW is different. In the vertical-cavity surface-emitting laser of this embodiment, each partition wall PW is connected to stack LM. Each partition wall PW may extend along main surface 12a. Both ends of each partition wall PW in the extension direction are connected to stack LM. The extension direction of partition wall PW is not limited. A plurality of partition walls PW may extend linearly parallel to each other.

According to the vertical-cavity surface-emitting laser of this embodiment, partition wall PW is supported by stack LM, which makes it difficult for partition wall PW to collapse.

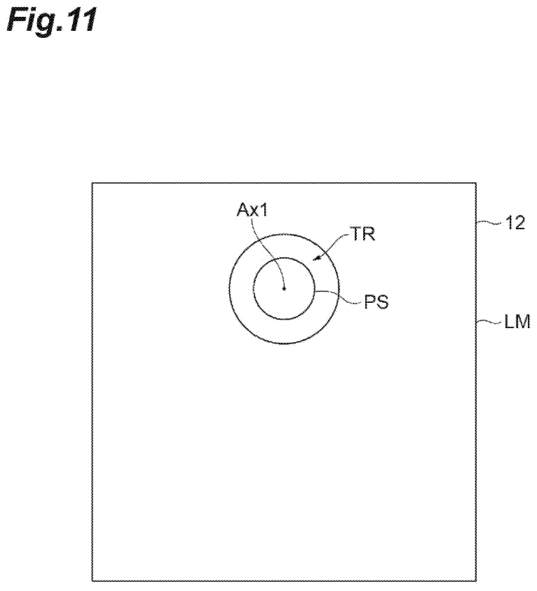

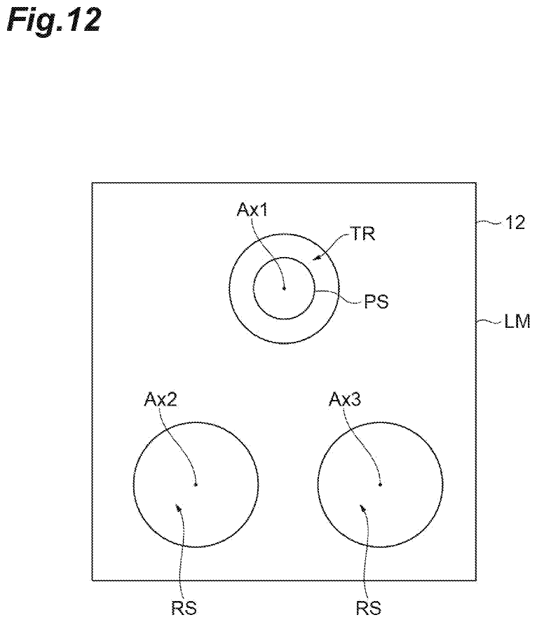

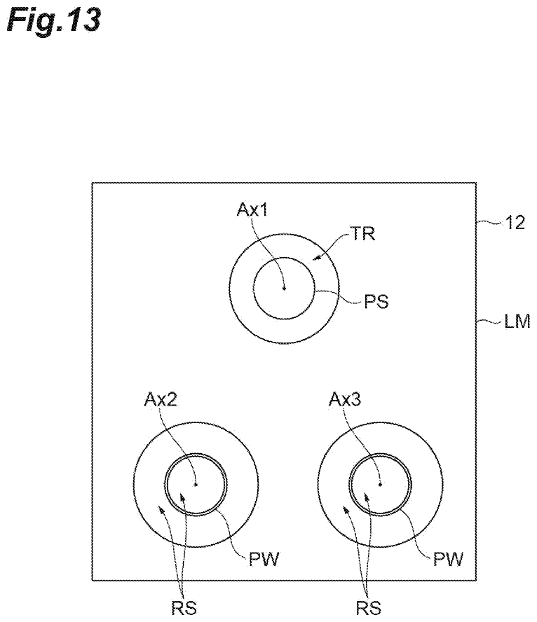

Each of FIGS. 11 to 15 shows a schematic view of a part of a vertical-cavity surface-emitting laser in the first through fifth experimental examples, respectively. In FIG. 11, structures on post PS, stack LM, and trench TR are omitted. In FIG. 12, structures on post PS, stack LM, recess portion RS, and trench TR are omitted. In FIGS. 13 to 15, structures on post PS, stack LM, partition wall PW, recess portion RS and trench TR are omitted.

The vertical-cavity surface-emitting laser of the first experimental example shown in FIG. 11 has the same configuration as vertical-cavity surface-emitting laser 10, except that recess portion RS and resin portion 60 are not provided. In the vertical-cavity surface-emitting laser of the first experimental example, electrode pad 34 and electrode pad 44 are provided on upper surface LMa of stack LM. There is no resin portion 60 between electrode pads 34, 44 and contact layer 16.

The vertical-cavity surface-emitting laser of the second experimental example shown in FIG. 12 has the same configuration as vertical-cavity surface-emitting laser 10, except that partition wall PW is not provided in each recess portion RS. In the vertical-cavity surface-emitting laser of the second experimental example, a single recess portion RS is provided above each of second area 12a2 and third area 12a3.

The vertical-cavity surface-emitting laser of the third experimental example shown in FIG. 13 has the same configuration as vertical-cavity surface-emitting laser 10, except that a single partition wall PW is provided in each recess portion RS. The vertical-cavity surface-emitting laser of the third experimental example has two recess portions RS above each of second area 12a2 and third area 12a3. Each partition wall PW has an annular shape with axis Ax2 or axis Ax3 as its center.

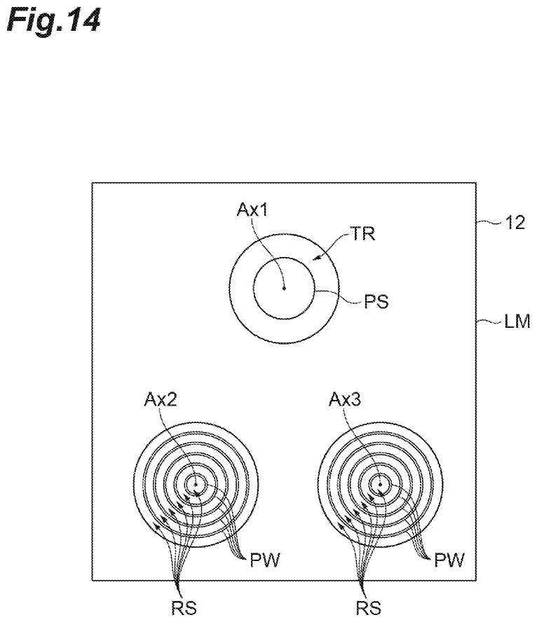

The vertical-cavity surface-emitting laser of the fourth experimental example shown in FIG. 14 has the same configuration as vertical-cavity surface-emitting laser 10, except that there are five partition walls PW in each recess portion RS. The vertical-cavity surface-emitting laser of the fourth experimental example has six recess portions RS above each of second area 12a2 and third area 12a3. The five partition walls PW are concentrically arranged with axis Ax2 or axis Ax3 as the center. Each partition wall PW has an annular shape with axis Ax2 or axis Ax3 as its center.

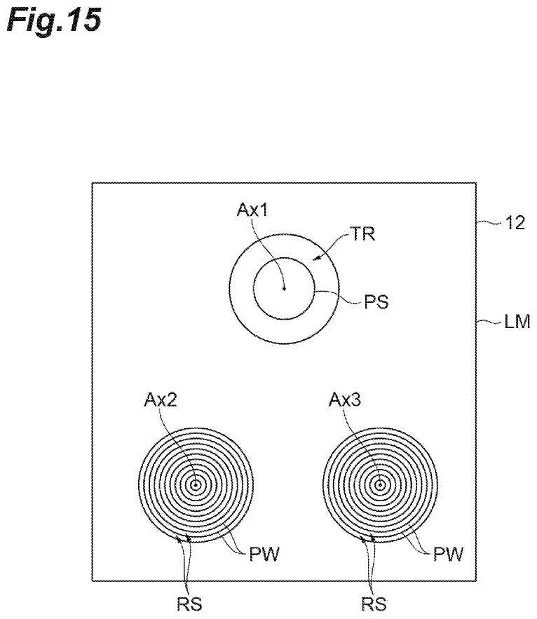

The vertical-cavity surface-emitting laser of the fifth experimental example shown in FIG. 15 has the same configuration as vertical-cavity surface-emitting laser 10, except that there are ten partition walls PW in each recess portion RS. The vertical-cavity surface-emitting laser of the fifth experimental example has eleven recess portions RS above each of second area 12a2 and third area 12a3. The ten partition walls PW are concentrically arranged with axis Ax2 or axis Ax3 as the center. Each partition wall PW has an annular shape with axis Ax2 or axis Ax3 as its center.

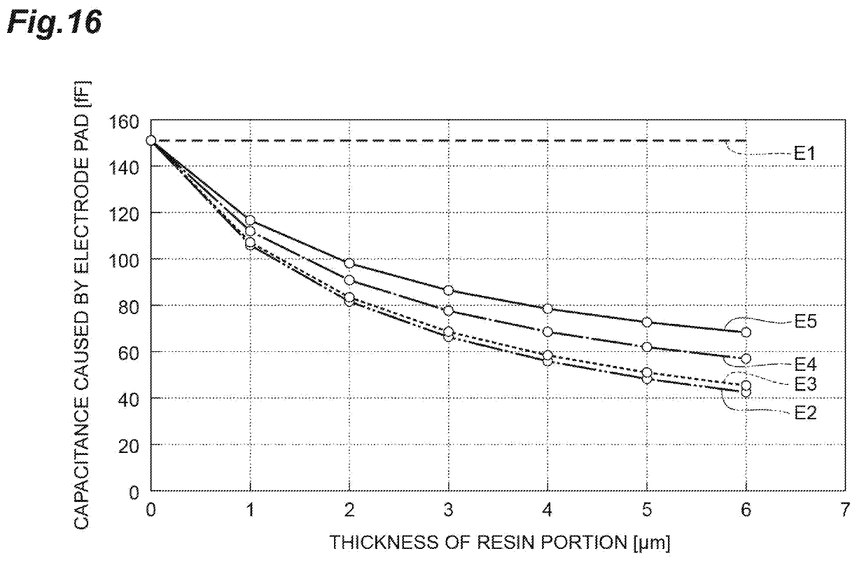

The capacitance between electrode pad 34 and contact layer 16 was measured for the vertical-cavity surface-emitting laser of the first experimental example. The capacitance between electrode pad 34 and contact layer 16 (the capacitance between parallel plates) was also measured for the vertical-cavity surface-emitting lasers of the second to fifth experimental examples, while varying the thickness H2 of resin portion 60. The width W of partition wall PW at upper surface PWa of partition wall PW was 1 μm. The results are shown in FIG. 16.

FIG. 16 shows the capacitances caused by the electrode pad in each vertical-cavity surface-emitting laser of the first through fifth experimental examples. The horizontal axis of the graph shows the thickness (μm) of the resin portion. The vertical axis of the graph shows the capacitance (fF) caused by the electrode pad. In the graph, E1 to E5 indicate the results of the first through fifth experimental examples, respectively. In the vertical-cavity surface-emitting laser of the first experimental example, the capacitance between electrode pad 34 and contact layer 16 was 150 fF. From the simulation results of the second to fifth experimental examples, it can be seen that the capacitance between electrode pad 34 and contact layer 16 decreases monotonically as the thickness H2 of resin portion 60 increases. It can also be seen that the capacitance between electrode pad 34 and contact layer 16 decreases monotonically as the number of recess portion RS or partition wall PW decreases. By setting the thickness H2 of resin portion 60 to 5 μm or more and the number of partition wall PW to five or less, the capacitance between electrode pad 34 and contact layer 16 can be suppressed to about 60 fF or less. In other words, the capacitance can be reduced by 60% or more.

Although suitable embodiments of the present disclosure have been described in detail above, the present disclosure is not limited to the above embodiments.

For example, a single recess portion RS may be placed on each of second area 12a2 and third area 12a3, or recess portion RS and resin portion 60 may not be placed on either second area 12a2 or third area 12a3.

The embodiments disclosed herein should be considered illustrative in all respects and not restrictive. The scope of the invention is indicated by the claims, not in the sense described above, and it is intended to include all modifications within the meaning and scope of the claims.

What is claimed is:

1. A vertical cavity surface emitting laser comprising:
a substrate comprising a main surface including a first area and a second area;
a post provided on or above the first area, the post including a first-conductive first distributed Bragg reflector provided on or above the first area, an active layer provided on the first distributed Bragg reflector, and a second-conductive second distributed Bragg reflector provided on the active layer;
a stack provided on or above the main surface, the stack including an upper surface comprising at least one recess portion disposed above the second area;
a resin portion disposed in the at least one recess portion; and
an electrode pad provided on the resin portion, the electrode pad electrically connected to either one of the first distributed Bragg reflector and the second distributed Bragg reflector.

2. The vertical cavity surface emitting laser according to claim 1,
wherein the at least one recess portion comprises a plurality of recess portions.

3. The vertical cavity surface emitting laser according to claim 2, further comprising a partition wall separating adjacent recess portions of the plurality of recess portions from each other,
wherein the partition wall has an annular shape when seen from a direction orthogonal to the main surface of the substrate.

4. The vertical cavity surface emitting laser according to claim 2, further comprising a plurality of partition walls, each of the plurality of partition walls separating adjacent recess portions of the plurality of recess portions from each other,
wherein each of the plurality of partition walls has an annular shape when seen from a direction orthogonal to the main surface of the substrate,
wherein the plurality of partition walls is concentrically arranged.

5. The vertical cavity surface emitting laser according to claim 2, further comprising a partition wall separating adjacent recess portions of the plurality of recess portions from each other,
wherein the partition wall is connected to the stack.

6. The vertical cavity surface emitting laser according to claim 5, wherein the partition wall extends along the main surface of the substrate.

7. The vertical cavity surface emitting laser according to claim 2, further comprising a plurality of partition walls, each of the plurality of partition walls separating adjacent recess portions of the plurality of recess portions from each other,
wherein each of the plurality of partition walls is connected to the stack,
wherein the plurality of partition walls extends linearly parallel to each other along the main surface of the substrate.

8. The vertical cavity surface emitting laser according to claim 3,
wherein the partition wall comprises an upper surface having a width of 1 μm or greater.

9. The vertical cavity surface emitting laser according to claim 3,
wherein the partition wall comprises a side surface inclined with respect to the main surface of the substrate, and
wherein an angle from the main surface to the side surface through an inner portion of the partition wall is less than 90°.

10. The vertical cavity surface emitting laser according to claim 3,
wherein the partition wall has the same layer structure as the stack.

11. The vertical cavity surface emitting laser according to claim 1,
wherein the stack has the same layer structure as the post.

12. The vertical cavity surface emitting laser according to claim 1,
wherein an upper surface of the stack is flush with an upper surface of the post.

13. The vertical cavity surface emitting laser according to claim 1, further comprising an insulating layer disposed between the at least one recess portion and the resin portion.

14. The vertical cavity surface emitting laser according to claim 1,
wherein the resin portion comprises benzocyclobutene or polyimide.

15. The vertical cavity surface emitting laser according to claim 1, further comprising a contact layer provided above the main surface,
wherein the contact layer extends from the first area to the second area,
wherein the contact layer is connected to the first distributed Bragg reflector, and
wherein the electrode pad is electrically connected to the second distributed Bragg reflector.

16. The vertical cavity surface emitting laser according to claim 15,
wherein a bottom of the at least one recess portion reaches an upper surface of the contact layer.

17. The vertical cavity surface emitting laser according to claim 15, further comprising an undoped third distributed Bragg reflector disposed between the substrate and the contact layer.
